(19) United States
(12) Patent Application Publication
(10) Pub. No.: US 2026/0026377 A1
(43) Pub. Date: Jan. 22, 2026

(54) PACKAGE SUBSTRATE AND MANUFACTURING METHOD THEREOF

(71) Applicant: SILICONWARE PRECISION INDUSTRIES CO., LTD., Taichung City (TW)

(72) Inventors: Pao-Hung TSENG, Taichung City (TW); Yu-Cheng PAI, Taichung City (TW); Yuan-Ping YEH, Taichung City (TW)

(21) Appl. No.: 18/896,446

(22) Filed: Sep. 25, 2024

(30) Foreign Application Priority Data
Jul. 16, 2024 (TW) 113126592

(51) Int. Cl. H01L 23/498; H01L 21/48

(52) U.S. Cl. CPC H01L 23/49838; H01L 21/4857; H01L 21/486; H01L 23/49827

(57) ABSTRACT

A package substrate is provided, in which at least one conductive trace is embedded in an insulating layer having a conductive through via and is electrically connected to the conductive through via, thereby facilitating the manufacture of the conductive trace with ultra-fine line width/line pitch specifications. Therefore, the wiring density can be increased in accordance with the requirements of the product functions.

### CROSS-REFERENCE TO RELATED APPLICATIONS

The present application is based upon and claims the right of priority to TW Patent Application No. 113126592, filed Jul. 16, 2024, the disclosure of which is hereby incorporated by reference herein in its entirety for all purposes.

### BACKGROUND

### 1. Technical Field

The present disclosure relates to a package substrate, and more particularly, to a package substrate and a manufacturing method thereof capable of meeting thinning requirements.

### 2. Description of Related Art

With the booming development of the electronics industry, electronic products tend to be thin, light, and small in shape, and move in the direction of high performance, high functionality, and high speed in function. To meet the high integration and miniaturization requirements of semiconductor devices, package substrates that can be thinned, have low warpage, and have high-density wiring designs are often used in the packaging process.

FIG. 1A to FIG. 1E are schematic cross-sectional views illustrating a manufacturing method of a conventional package substrate 1.

As shown in FIG. 1A, a core layer 10 having a metal layer 11 at an upper side and a lower side, respectively, is provided.

As shown in FIG. 1B, a funnel-shaped through hole 100 is formed on the core layer 10 and penetrates through the core layer 10 and the metal layers 11. A conductive layer 12 is then formed on the metal layers 11 and on a hole wall of the through hole 100.

As shown in FIG. 1C, a resist layer 19 having a patterned opening 190 is formed on the conductive layer 12 on the metal layers 11. Subsequently, a wiring layer 14 is formed within the opening 190 of each of the resist layers 19, and a conductive through via 13 is formed in the through hole 100 and is electrically connected to the wiring layers 14. The wiring layer 14 has a line width/line pitch of 20 microns/20 microns.

As shown in FIG. 1D, the resist layers 19 and the underlying conductive layer 12 and the metal layers 11 are removed.

As shown in FIG. 1E, a circuit structure 15 is formed on the upper side and the lower side of the core layer 10, respectively, and each of the circuit structures 15 is electrically connected to each of the wiring layers 14. A solder mask layer 16 is then formed on each of the circuit structures 15. The circuit structure 15 includes a dielectric layer 150 and a circuit layer 151 electrically connected to the wiring layer 14. The circuit layer 151 has a line width/line pitch of 20 microns/20 microns.

However, a manufacturing method of the conventional package substrate is limited by the traditional manufacturing process of forming wiring layers 14 with larger line width/line pitch on the upper and lower sides of the core layer 10. In order to meet the thin line requirements of the product functions, the circuit structure 15 must be formed on the upper and lower sides of the core layer 10, which makes it difficult to reduce the number of wiring layers (e.g., eight layers in total, including upper and lower layers) of the conventional package substrate 1 and cannot meet the thinning requirements.

In addition, the conventional package substrate 1 requires the fabrication of multiple circuit layers 151 on the core layer 10 to achieve the required product functions, but each layer of the package substrate has a yield loss when building up the layers. Therefore, as the number of the circuit layer 151 increases, the yield of the circuit layer 151 decreases, thereby rendering improvement of the yield during the manufacturing of the circuit structure 15 challenging.

Therefore, how to overcome the above problems of the prior art has become an urgent problem to be solved.

### SUMMARY

In view of the various deficiencies of the prior art, the present disclosure provides a package substrate, which comprises: an insulating layer having at least one conductive through via penetrating through the insulating layer; and a conductive trace embedded in the insulating layer and electrically connected to the conductive through via.

The present disclosure further provides a method of manufacturing a package substrate, the method comprises: providing a plurality of carriers each having a metal layer; forming a conductive trace on the metal layer to form a plurality of substrate structures; bonding the plurality of substrate structures to two opposite sides of an insulating layer via the metal layer, wherein the conductive trace is embedded in the insulating layer; removing the carriers to expose the conductive trace; and forming at least one conductive through via penetrating through the insulating layer on the conductive trace and electrically connecting the conductive through via to the conductive trace.

In the aforementioned package substrate and method, the conductive trace has a line width/line pitch of 7 microns/10 microns.

In the aforementioned package substrate and method, the present disclosure further comprises removing a partial material of the conductive trace when removing the metal layer, allowing a surface of the conductive trace to be lower than a surface of the insulating layer to form a recessed portion.

In the aforementioned package substrate and method, the present disclosure further comprises forming a pad portion stacked on the conductive trace at an end of the conductive through via.

In the aforementioned package substrate and method, the present disclosure further comprises forming a circuit structure on the insulating layer and electrically connecting the circuit structure to the conductive trace or the conductive through via. For instance, the circuit structure includes at least one dielectric layer and at least one circuit layer electrically connected to the conductive trace or the conductive through via. Further, a line width/line pitch of the conductive trace is less than a line width/line pitch of the circuit layer. Alternatively, the present disclosure comprises forming an insulating protective layer on the circuit structure.

As can be seen from the above, the package substrate and manufacturing method of the present disclosure mainly embed the conductive traces within the insulating layer, thereby facilitating the manufacture of the conductive traces with ultra-fine line width/line pitch specifications. The present disclosure is advantageous for increasing the wiring density in accordance with the requirements of the product functions, and can be disposed with or without the circuit structure as needed. Accordingly, compared with the prior art, the package substrate of the present disclosure can significantly reduce the number of total wiring layers to simultaneously meet the requirements of product functionality and thinness.

Furthermore, even when the circuit structure is disposed, the number of circuit layers is less than the number of conventional circuit layers. Accordingly, compared with the prior art, the package substrate of the present disclosure, even when the circuit structure is built up, can significantly reduce the number of layers of the total wiring so as to simultaneously meet the requirements of product functionality and thinness.

In addition, the package substrate of the present disclosure can achieve the required product functions with a reduced number of total wiring layers on the insulating layer. Accordingly, compared with the prior art, the manufacturing method of the present disclosure can significantly improve the yield in the manufacture of the circuit structure.

### BRIEF DESCRIPTION OF THE DRAWINGS

FIG. 1A to FIG. 1E are schematic cross-sectional views illustrating a manufacturing method of a conventional package substrate.

FIG. 2A to FIG. 2H are schematic cross-sectional views illustrating a manufacturing method of a package substrate according to the present disclosure.

FIG. 3 is a schematic cross-sectional view of another aspect of the package substrate according to the present disclosure.

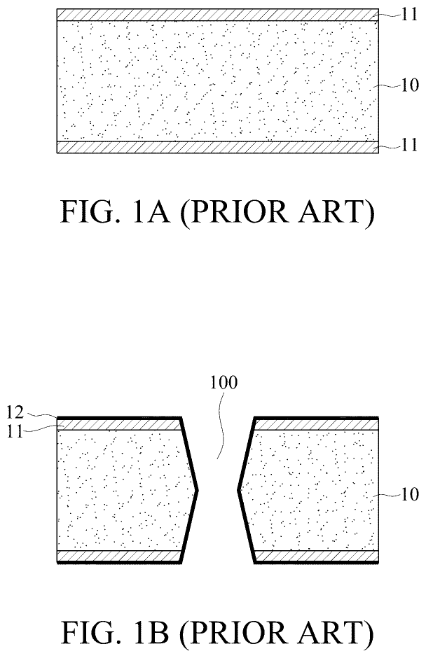

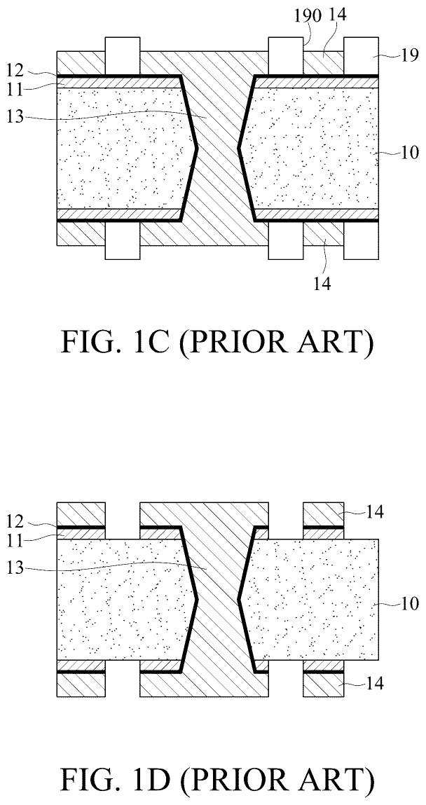

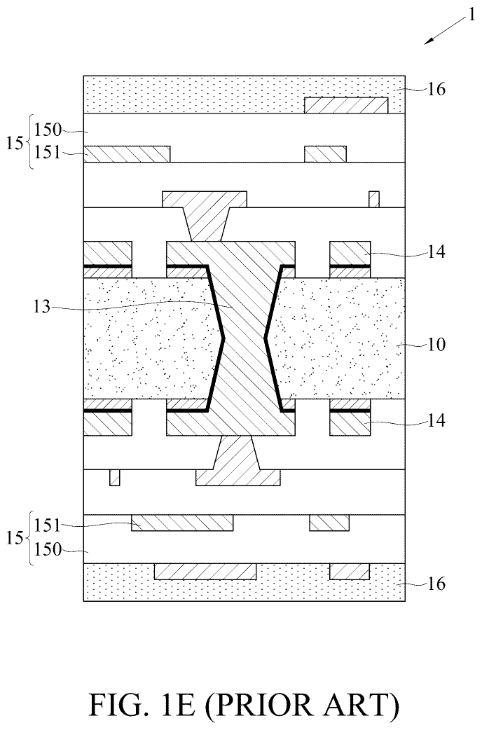

### DETAILED DESCRIPTION

The following describes the embodiments of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “upper,” “first,” “second,” “a,” “one” and the like are merely for clear explanation rather than limiting the practicable scope of the present disclosure, and thus, alterations or adjustments of the relative relationships thereof without essentially altering the technical contents should still be considered in the practicable scope of the present disclosure.

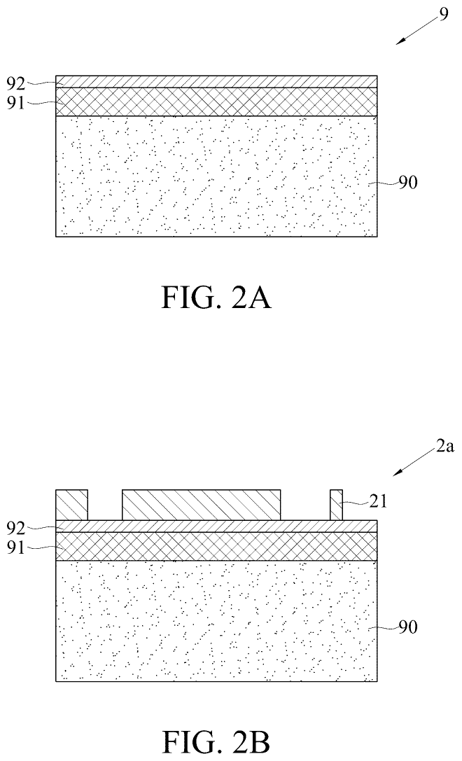

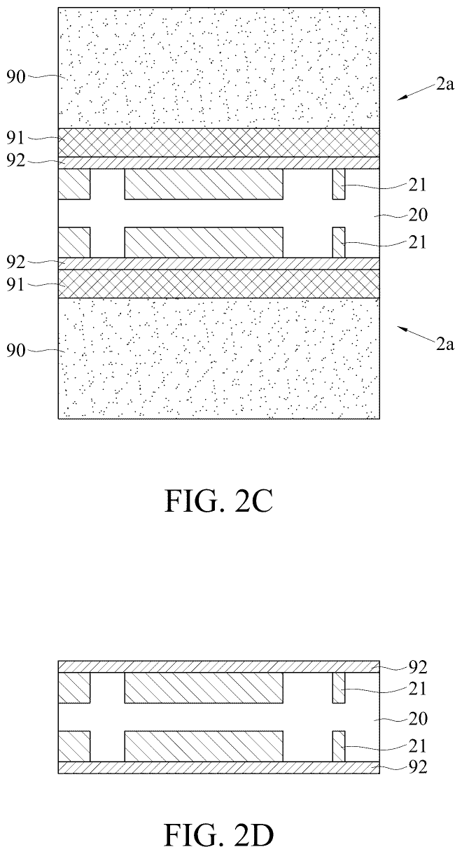

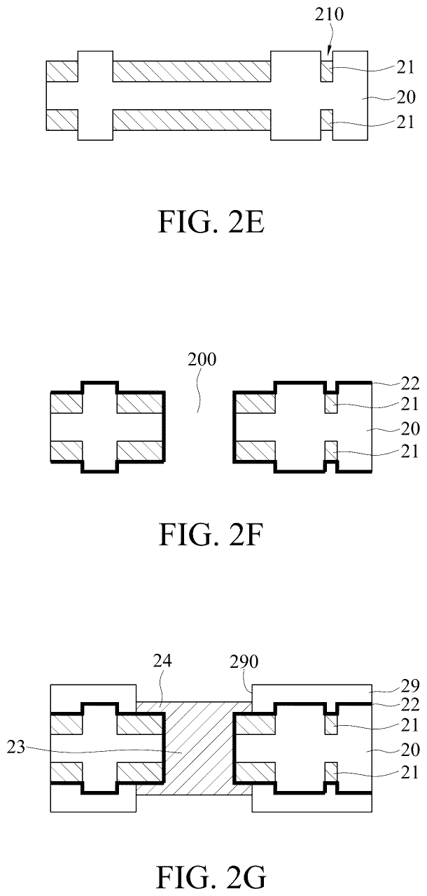

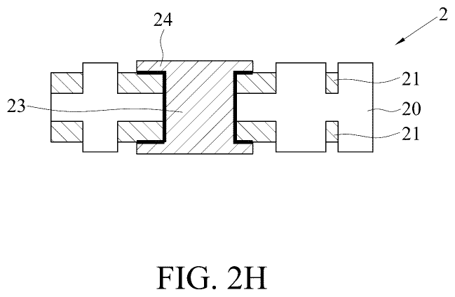

FIG. 2A to FIG. 2H are schematic cross-sectional views illustrating a manufacturing method of a package substrate 2 according to the present disclosure.

As shown in FIG. 2A, a plurality of carriers 9 are provided. Only a single carrier 9 is depicted in FIG. 2A for the sake of simplicity. The carrier 9 includes a board 90, a release layer 91 formed on a side of the board 90, and a metal layer 92 formed on the release layer 91.

In an embodiment, the board 90 is a temporary carrier board, and the metal layer 92 is a copper foil.

As shown in FIG. 2B, a patterning wiring process is performed via the metal layer 92. A conductive trace 21 is formed on the metal layer 92 to form a substrate structure 2a.

In an embodiment, the metal layer 92 serves as a seed layer for electroplating a copper layer as the conductive trace 21.

In addition, the conductive trace 21 has an ultra-fine line width/line pitch specification, such as 7 microns/10 microns.

As shown in FIG. 2C, a plurality of substrate structures 2a are bonded to two opposite sides of an insulating layer 20 via respective metal layer 92.

In an embodiment, each of the substrate structures 2a is bonded to the insulating layer 20 by means of lamination so that each of the conductive traces 21 is embedded in the insulating layer 20 to form an embedded circuit.

In addition, the insulating layer 20 is made of, for example, prepreg (PP), polybenzoxazole (PBO), polyimide (PI), or other dielectric materials.

As shown in FIG. 2D, the boards 90 are removed via the release layers 91, leaving the metal layers 92 on the two opposite sides of the insulating layer 20.

As shown in FIG. 2E, the metal layers 92 are removed to expose surfaces of the insulating layer 20 and the conductive traces 21.

In an embodiment, the metal layer 92 is removed by means of etching, and a partial material of the conductive trace 21 is micro-etched, so that a surface of the conductive trace 21 is lower than a surface of the insulating layer 20 to form a recessed portion 210.

As shown in FIG. 2F, corresponding to the conductive traces 21, at least one through hole 200 is formed on the conductive traces 21 and penetrates through the insulating layer 20, and a conductive layer 22 is then formed on the conductive traces 21 and the insulating layer 20 and on a hole wall of the through hole 200.

In an embodiment, the conductive layer 22 is formed by means of a copper process, and the through hole 200 is formed by means of a laser, without particularly limiting the shape. For instance, the through hole 200 can have the shape of a straight tube (as shown in FIG. 2F), a cone, or a funnel.

As shown in FIG. 2G, a resist layer 29 having a patterned opening 290 is formed on the conductive layer 22 on the conductive traces 21 and the insulating layer 20. A partial surface of the conductive layer 22 is exposed from the opening 290, and a conductive through via 23 is formed in the through hole 200 and is electrically connected to the conductive traces 21.

In an embodiment, the opening 290 exposes the through hole 200 and the conductive layer 22 around the through hole 200, so that an end of the conductive through via 23 located around the through hole 200 forms a pad portion 24 stacked on the conductive trace 21. For instance, the conductive through via 23 and the pad portions 24 are formed by means of electroplating copper material.

As shown in FIG. 2H, the resist layers 29 and the underlying conductive layer 22 are removed to expose a surface of the insulating layer 20 and the conductive trace 21. As such, the package substrate 2 is obtained.

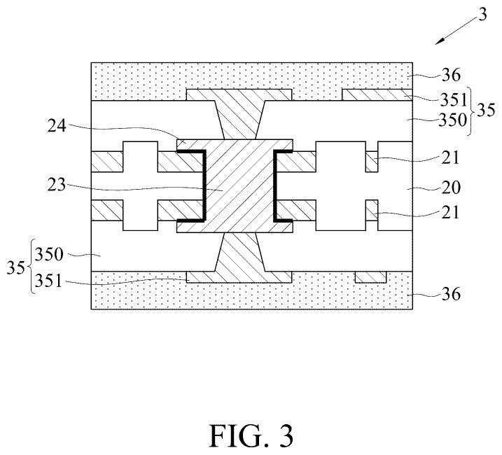

Please refer to FIG. 3. In an embodiment, a circuit structure 35 can be formed on each of the two opposite sides of the insulating layer 20 as needed, and the circuit structure 35 is electrically connected to the conductive trace 21 or the conductive through via 23. An insulating protective layer 36, made of such as solder mask material, can be formed on each of the circuit structures 35. As such, another package substrate 3 is obtained.

In an embodiment, the circuit structure 35 includes at least one dielectric layer 350 and at least one circuit layer 351 electrically connected to the conductive trace 21 or the conductive through via 23. For instance, the circuit layer 351 is made of copper material and with a redistribution layer (RDL) specification.

Moreover, a line width/line pitch of the conductive trace 21 is less than a line width/line pitch of the circuit layer 351. For instance, the line width/line pitch of the circuit layer 351 is 20 microns/20 microns.

In addition, the dielectric layer 350 is made of Ajinomoto build-up film (ABF), polybenzoxazole (PBO), polyimide (PI), prepreg (PP), or other dielectric materials. The insulating protective layer 36 may be made of green ink (e.g., solder resist material).

Therefore, the manufacturing method of the present disclosure mainly forms the conductive traces 21 with ultra-fine line width/line pitch specifications and embeds the conductive traces 21 in the two opposite surfaces of the insulating layer 20, thereby facilitating for increasing the wiring density according to the needs of the product functions, and the circuit structure 35 can be optionally disposed as needed. Accordingly, compared with the prior art, the package substrate 2 of the present disclosure can significantly reduce the number of total wiring layers (two layers for upper and lower layers as shown in FIG. 2H) to simultaneously meet the requirements of product functionality and thinness.

Furthermore, even when the circuit structure 35 is disposed, the number of the circuit layers 351 (e.g., two layers in total, including upper and lower layers) is less than the number of the conventional circuit layers 151 (e.g., six layers in total, including upper and lower layers). Accordingly, compared with the prior art, the package substrate 3 of the present disclosure, even when the circuit structure 35 is built up, can significantly reduce the number of layers (e.g., four layers in total, including upper and lower layers as shown in FIG. 3) of the total wiring (including the conductive traces 21 and the circuit layers 351), so as to simultaneously meet the requirements of product functionality and thinness.

In addition, the package substrate 3 of the present disclosure can achieve the required product functions with a reduced number of total wiring layers (e.g., four layers in total, including upper and lower layers as shown in FIG. 3) on the insulating layer 20. Accordingly, compared with the prior art, the manufacturing method of the present disclosure can significantly improve the yield in the manufacture of the circuit structure 35 with a reduced number of layers.

The present disclosure also provides a package substrate 2, 3, which includes: an insulating layer 20 and at least one conductive trace 21.

The insulating layer 20 includes at least one conductive through via 23 penetrating through the insulating layer 20.

The conductive trace 21 is embedded in the insulating layer 20 and is electrically connected to the conductive through via 23.

In an embodiment, the conductive trace 21 has a line width/line pitch of 7 microns/10 microns.

In an embodiment, a surface of the conductive trace 21 is lower than a surface of the insulating layer 20 to form a recessed portion 210.

In an embodiment, an end of the conductive through via 23 is formed with a pad portion 24 stacked on the conductive trace 21.

In an embodiment, the package substrate 3 further includes a circuit structure 35 formed on the insulating layer 20 and electrically connected to the conductive trace 21 or the conductive through via 23. For instance, the circuit structure 35 includes at least one dielectric layer 350 and at least one circuit layer 351 electrically connected to the conductive trace 21 or the conductive through via 23. Further, a line width/line pitch of the conductive trace 21 is less than a line width/line pitch of the circuit layer 351. Alternatively, the package substrate 3 further includes an insulating protective layer 36 formed on the circuit structure 35.

In conclusion, the package substrate and manufacturing method of the present disclosure mainly form the conductive traces with ultra-fine line width/line pitch specifications and embed the conductive traces in the insulating layer, thereby facilitating for increasing the wiring density according to the needs of the product functions. Accordingly, the package substrate of the present disclosure can significantly reduce the number of total wiring layers to simultaneously meet the requirements of product functionality and thinness.

Furthermore, even when the circuit structure is disposed, the number of circuit layers is less than the number of conventional circuit layers. Accordingly, the package substrate of the present disclosure, even when the circuit structure is built up, can significantly reduce the number of layers of the total wiring so as to simultaneously meet the requirements of product functionality and thinness.

In addition, the package substrate of the present disclosure can achieve the required product functions with a reduced number of total wiring layers on the insulating layer. Accordingly, the manufacturing method of the present disclosure can significantly improve the yield in the manufacture of the circuit structure.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. A package substrate, comprising:
an insulating layer formed with at least one conductive through via penetrating through the insulating layer; and
a conductive trace embedded in the insulating layer and electrically connected to the conductive through via.

2. The package substrate of claim 1, wherein the conductive trace has a line width/line pitch of 7 microns/10 microns.

3. The package substrate of claim 1, wherein a surface of the conductive trace is lower than a surface of the insulating layer to form a recessed portion.

4. The package substrate of claim 1, wherein an end of the conductive through via is formed with a pad portion stacked on the conductive trace.

5. The package substrate of claim 1, further comprising a circuit structure formed on the insulating layer and electrically connected to the conductive trace or the conductive through via.

6. The package substrate of claim 5, wherein the circuit structure includes at least one dielectric layer and at least one circuit layer electrically connected to the conductive trace or the conductive through via.

7. The package substrate of claim 6, wherein a line width/line pitch of the conductive trace is less than a line width/line pitch of the circuit layer.

8. The package substrate of claim 5, further comprising an insulating protective layer formed on the circuit structure.

9. A method of manufacturing a package substrate, the method comprising:
providing a plurality of carriers each having a metal layer;
forming a conductive trace on the metal layer of each of the carriers to form a plurality of substrate structures;
bonding the plurality of substrate structures to two opposite sides of an insulating layer via the metal layer, wherein the conductive trace is embedded in the insulating layer;
removing the carriers to expose the conductive trace; and
forming at least one conductive through via penetrating through the insulating layer on the conductive trace and electrically connecting the conductive through via to the conductive trace.

10. The method of claim 9, wherein the conductive trace has a line width/line pitch of 7 microns/10 microns.

11. The method of claim 9, further comprising removing a partial material of the conductive trace when removing the metal layer, allowing a surface of the conductive trace to be lower than a surface of the insulating layer to form a recessed portion.

12. The method of claim 9, further comprising forming a pad portion stacked on the conductive trace at an end of the conductive through via.

13. The method of claim 9, further comprising forming a circuit structure on the insulating layer and electrically connecting the circuit structure to the conductive trace or the conductive through via.

14. The method of claim 13, wherein the circuit structure includes at least one dielectric layer and at least one circuit layer electrically connected to the conductive trace or the conductive through via.

15. The method of claim 14, wherein a line width/line pitch of the conductive trace is less than a line width/line pitch of the circuit layer.

16. The method of claim 13, further comprising forming an insulating protective layer on the circuit structure.
